(19) United States
(12) Patent Application Publication
(10) Pub. No.: US 2005/0168260 A1
(43) Pub. Date: Aug. 4, 2005

(54) Configurable delay line circuit

(76) Inventors: Andrew T. Tomerlin, Coral Springs, FL (US); Robert E. Stengel, Pompano Beach, FL (US)

Correspondence Address: Larson & Associates, P.C., 221 East Church Street, Frederick, MD, 21701-5405, US

(21) Appl. No.: 10/767,088

(22) Filed: Jan. 29, 2004

(51) Int. Cl. H03H 11/26

(52) U.S. Cl. 327/278

(57) ABSTRACT

A configurable circuit consistent with certain embodiments has a variable length delay line (10), the delay line (10) having an input (24) and having N delay elements (12, 14, 16, 18, . . . , 20) to provide a plurality of N delayed outputs (T(0) through T(N)). The variable length delay line (10) also has a number of active delay elements determined by a program command. A configurable processing array (32) receives the delayed outputs from the active delay elements and secondary data (38). The configurable processing array has an array of configurable circuit elements (104, 130, 150). The configurable processing array is configured to process the delayed outputs and the secondary data (38) in a manner for which the invention is to be used. This abstract is not to be considered limiting, since other embodiments may deviate from the features described in this abstract.

### BACKGROUND

Cellular and wireless telephones, as well as other portable wireless devices benefit from reduced power consumption, compact circuitry, and software defined circuitry. When power consumption is reduced, battery life is extended and a user can operate the device for a longer period of time before replacing or recharging the batteries. When circuit size is reduced, the device can be made more portable and sometimes can be made less expensively. When a circuit function can be defined by software, a given segment of circuitry can potentially be used for many applications. This often benefits manufacturers and consumers by permitting the manufacturer to benefit from the economies of scale to reduce costs.

### BRIEF DESCRIPTION OF THE DRAWINGS

The features believed to be novel are set forth with particularity in the appended claims. The organization and method of operation, objects and advantages thereof, may be best understood by reference to the following detailed description, which describes certain exemplary embodiments, taken in conjunction with the accompanying drawings in which:

FIG. 1 is a block diagram consistent with certain embodiments of the present invention.

FIG. 2 is a block diagram of a variable delay line consistent with certain embodiments of the present invention.

FIG. 3 is a block diagram of an ALU (Arithmetic Logic Unit) based PU (Processing Unit) consistent with certain embodiments of the present invention.

FIG. 4 is a block diagram of a multiplier based PU consistent with certain embodiments of the present invention.

FIG. 5 is a block diagram of an ALU (Arithmetic Logic Unit) based PU (Processing Unit) with detailed multiplexing circuitry consistent with certain embodiments of the present invention.

FIG. 6 is a block diagram of the configurable circuit of FIG. 1 configured to operate as a frequency multiplier consistent with certain embodiments of the present invention.

FIG. 7 is a block diagram of the configurable circuit of FIG. 1 configured to operate as a CDMA (Code Division Multiple Access) correlator circuit in a manner consistent with certain embodiments of the present invention.

### DETAILED DESCRIPTION

While this invention is susceptible of embodiment in many different forms, there is shown in the drawings and will herein be described in detail specific embodiments, with the understanding that the present disclosure is to be considered as an example of principles and not intended to limit the invention to the specific embodiments shown and described. In the description below, like reference numerals are used to describe the same, similar or corresponding elements in the several views of the drawings.

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically. The term “program”, as used herein, is defined as a sequence of instructions designed for execution on a computer system. A “program”, or “computer program”, may include a subroutine, a function, a procedure, an object method, an object implementation, in an executable application, an applet, a servlet, a source code, an object code, a shared library/dynamic load library and/or other sequence of instructions designed for execution on a computer system.

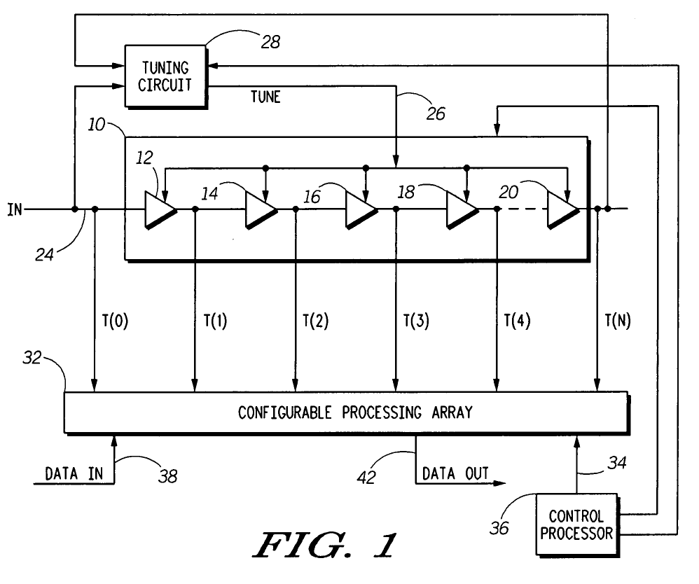

With reference to FIG. 1, a configurable delay line circuit is depicted in which a delay line 10 is made up of a plurality of N series connected delay elements 12, 14, 16, 18 through 20. Each of these N delay elements has an input and an output with the delay elements cascaded together so that an input pulse applied at input node 24 produces N delayed versions at the outputs of each of the N delay elements, with each output delayed by a delay of approximately D. These N delayed versions appear at each of the output taps T(1) through T(N). The original input signal may be made available at tap T(0). The delay of each of the delay elements can be individually and/or collectively adjusted so that the value of D for each delay is approximately the same and is of a desired value by controlling one or more TUNE signals (one shown in this illustration) 26 applied to the delay line. The TUNE input signal 26 can be generated and controlled in a tuning circuit 28 that can operate in any number of ways, such as for example, by locking the signal cascading through the delay line to a delay locked loop.

In accordance with certain embodiments, the delay line can be made to be effectively a variable length delay line by selectively using or ignoring output taps as desired to implement a particular function. Thus, the delay line may be made to be a maximum desired length (e.g., N taps), and certain tap outputs (e.g., taps N−5 through N) simply ignored, powered down, disabled and/or not connected. In certain embodiments, multiple parallel delay lines may be used. In certain embodiments the delay elements can be implemented as differential delay line circuits rather than the single-ended circuits shown herein for simplicity.

The tap outputs T(0) through T(N) (or T(1) through T(N) or any other combination), or a subset thereof, are inputs to a configurable processing array 32 for use in programming the function for which the delay line is to be used. The configurable processing array, 32, inputs the tap outputs from the delay line, 10, and secondary data, 38. The configurable processing array, 32, processes the tap outputs with secondary data 38 in a manner for which the invention is to be used. The configurable processing array 32, in certain embodiments, may be made up of an array of arithmetic logic units (ALU) or multipliers which together with other logic structures are commonly referred to as Processing Units (PU). Each PU is software configurable by executing a set of assembly instructions controlled by the control processor (CP) 36.

In other embodiments, the configurable processing array can be realized with a programmable logic device or any other suitable device with a structure that permits the device to have a programmable function. Thus, the term “configurable processing array” is used herein to mean a circuit arrangement that can be configured to carry out any number of circuit functions. This term can encompass devices commonly known as “reconfigurable processing arrays” as well as “programmable logic devices”, programmable logic arrays, programmable gate arrays and similar devices that can receive programming instructions and configure or reconfigure it's internal functionality to carry out a specific function defined by those programming instructions.

The control processor 36 receives as inputs system parameters that may include, but are not limited to, delay line speed, number of taps used and processing parameters. The control processor 36 then outputs delay line speed control signals (e.g., a reference clock) to the tuning circuit 28, number of taps for processing control to the variable delay line 10 and processing control commands to the configurable processing array 32.

The variable delay line 10 can shut off or disconnect delay elements that are not to be used in the currently programmed process. In certain embodiments, the tuning circuit incorporates a delay locked loop structure. In this embodiment, an external reference clock (e.g., from the control processor) is provided as an input and produces an output TUNE signal 26 that is produced as a part of a feedback control system to set the delay of the delay line elements. Another embodiment of the tuning circuit incorporating a delay lock loop structure is the input, 24, a reference clock inputted into both the tuning circuit, 28, and the delay line, 10. The output of the Nth delay element, T(N), is also an input of the tuning circuit, 28. The tuning circuit locks the input reference clock, 24, and the output of the Nth delay element, T(N), to one or more wavelengths of the reference clock.

The delay line 10, as illustrated, has N delay elements connected in series. In certain embodiments, these delay elements can each be made up of a pair of inverters that together form a buffer element. The output and/or input of each delay element can be individually controlled to shut down, go inactive, remain active, switched using switching circuitry or multiplexers, or can otherwise be selectively connected under program control. The term “active”, is therefore used herein to indicate that a tap of the delay line associated with a particular delay is provided and actively used in the currently programmed circuit function. This is implemented, as will be described later, in certain embodiments by use of a programmable multiplexer which switches the signal at “active” taps to a set of output lines of the variable delay line 10.

The variable length delay line can also be controlled via the TUNE signal or signals 26 to change the delay time for propagation of signals therethrough. This can be accomplished in certain embodiments by use of a pair of inverters for the delay elements and controlling current sources forming a part of the inverters in order to adjust the delay time of the inverters.

The delay line can be implemented to respond to two commands, a window length command, and a tuning command (e.g., a tuning voltage=TUNE signal). The window length command inactivates, shuts off or disconnects unneeded taps. The delay of each of the delay elements is adjusted as a result of the TUNE signal 26 (e.g., a tuning voltage), and a window of operational taps is provided as output to the configurable processing array 32.

The configurable processing array 32 can take on many configurations, but in certain embodiments incorporates an array of multipliers or ALUs forming a part of PUs as described above. Each PU can be software configurable (and possibly reconfigurable) by execution of a sequence of instructions input at 34 from the control processor. The configurable processing array 32 may receive input data from one or more data inputs 38 along with the window of tap outputs from the variable delay line 10. The configurable processing array 32 can then carry out any suitable programmed process using this data as input to produce an output at one or more data outputs 42. In many cases, all PUs are not utilized to realize a particular circuit configuration. In these cases, the unused PUs can be placed in a “sleep” or disabled mode in which little or no current is consumed to thereby reduce power consumption requirements.

Although shown as separate functional blocks, it should be noted that the delay line architecture shown could be integrated within the same circuit as the configurable processing array (i.e., fabricated on the same integrated circuit chip) in certain embodiments. In other embodiments, the circuits can remain separate as illustrated.

Thus, a configurable circuit consistent with certain embodiments has a variable length delay line 10, the delay line having an input 24 and having N delay elements 12, 14, 16, 18, . . . , 20 to provide a plurality of N delayed outputs. The variable length delay line 10 also has a number of active delay elements determined by a program command. A configurable processing array 32 receives the delayed outputs from the active delay elements. The configurable processing array 32 receives secondary input data 38 and delayed outputs from the delay line 10. The configurable processing array has an array of configurable circuit elements.

In other embodiments, a configurable circuit, has a variable length delay line, the delay line having an input and having N delay elements to provide a plurality of N delayed outputs. The N delay elements each have a pair of series connected inverters. The variable length delay line has a number of active delay elements determined by a program command. A configurable processing array receives the delayed outputs from the active delay elements and secondary input data 38, the configurable processing array having an array of configurable circuit elements. A control processor configures the number of active delay elements of the variable length delay line and configures the array of configurable circuits. A delay locked loop controls the delay of the N delay elements.

In operation, a method of performing a circuit function can be carried out according to certain embodiments by applying an input to a variable length delay line, the delay line having an input and having N delay elements to provide a plurality of N delayed outputs, the variable length delay line having a number of active delay elements determined by a program command; and applying the delayed outputs of the active delay elements to a configurable processing array receiving the delayed outputs from the active delay elements and secondary data 38, the configurable processing array comprising an array of configurable circuits that have been configured under program control to carry out a circuit function.

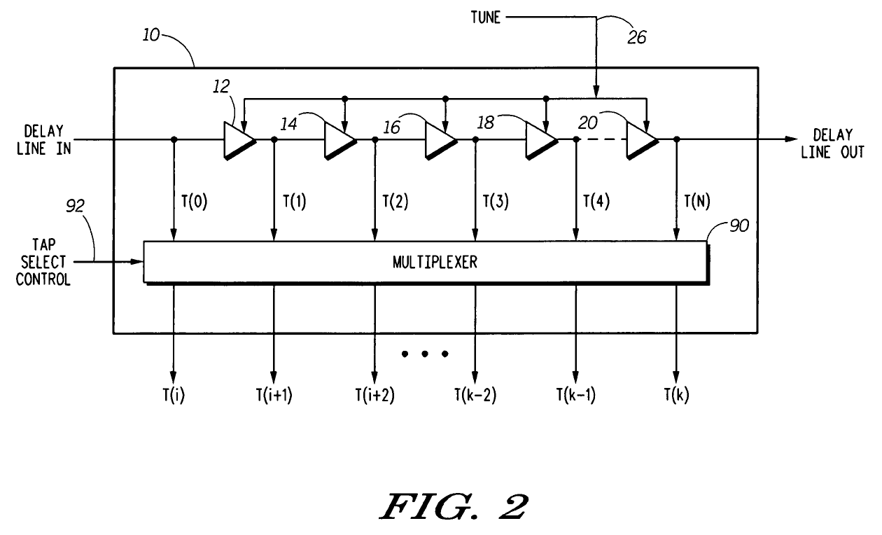

FIG. 2 depicts a more detailed view of certain embodiments consistent with a variable delay line 10. In this embodiment, a multiplexer (mux) 90 is coupled to the tapped delay line structure at each of the delay line's taps T(0) through T(N). Operating under program control via the tap select control input 92, multiplexer 90 selects (K+1) taps to be provided as outputs where, in this example, K+1≦N+1. In some cases T(0) might not be supplied to the multiplexer, in which case K+1≦N. Thus, in this example, any suitable window of taps (consecutive or non-consecutive, contiguous or non-contiguous) could be programmed as outputs to be used in conjunction with the configurable processing array as described to carry out one or more functions.

Thus, a variable delay line consistent with certain embodiments has a plurality of N delay elements with each delay having an input and an output, the N delay elements being coupled together in series output to input to form a delay line. A programming input receives a program control command. A programmable multiplexer responds to the program control command to selectively enable a selected group of delay elements, while disabling remaining delay elements.

In certain other embodiments, a variable delay line has a plurality of N delay elements with each delay having an input and an output, the N delay elements being coupled together in series output to input to form a delay line, A programming input receives a program control command. A programmable multiplexer, responds to the program control command to selectively enable a selected group of delay elements while disabling remaining delay elements. The delay of the N delay elements is controlled by a signal applied to a delay control input.

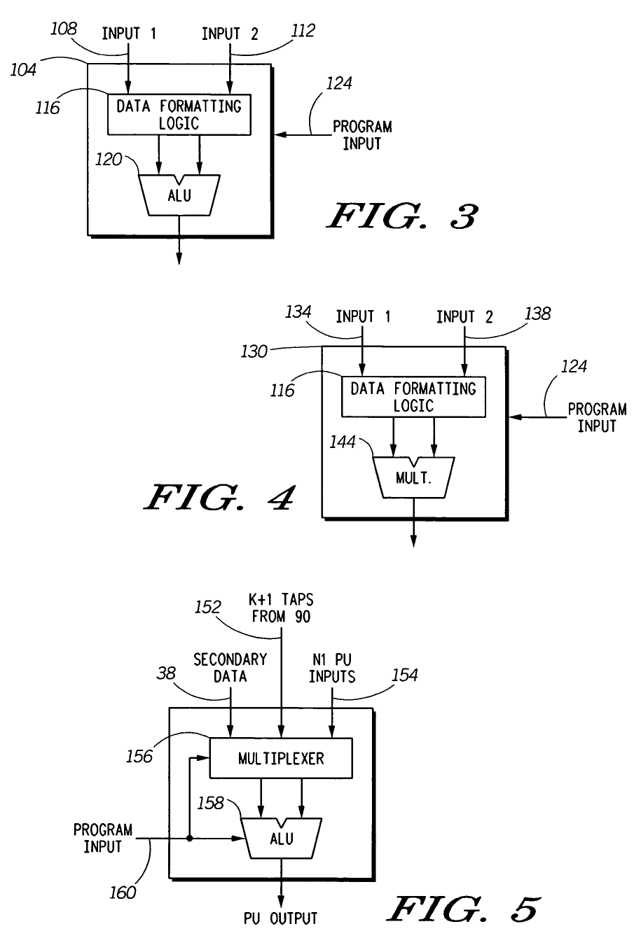

As previously mentioned, in certain embodiments the configurable processing array can be made up of an array of processing units (PUs). FIG. 3 depicts an ALU based PU 104 having a pair of inputs (but one or more inputs could be used) 108 and 112. The PU inputs, 108 and 112, are tap outputs from the selectable mux 90, secondary data 38, or other PU outputs. These inputs are supplied to data formatting logic circuitry 116, which can be configured to manipulate the logic in any desired fashion including performing a serial to parallel conversion and/or other functions. The data formatting logic circuitry 116 outputs data to the inputs of an ALU 120 which can be programmed (along with data formatting logic circuit 116) via the program input 124 to carry out the desired action for this particular PU.

Similarly, FIG. 4 depicts a multiplier based PU 130 having a pair of inputs (but one or more inputs could be used) 134 and 138. These inputs are also supplied to data formatting logic circuitry 116, which can be configured to manipulate the logic in any desired fashion including performing a serial to parallel conversion and/or other functions. The PU inputs, 134 and 138, are tap outputs from the selectable mux 90, secondary data 38, or other PU outputs. The data formatting logic circuitry 116 outputs data to the inputs of a multiplier 144 which can be programmed (along with data formatting logic circuit 116) via the program input 124 to carry out the desired action for this particular PU.

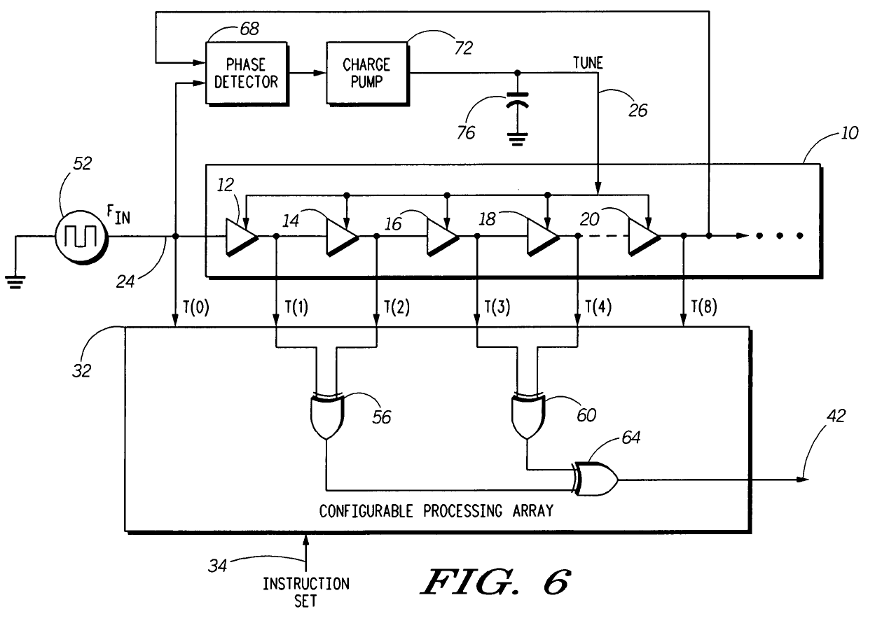

A more detailed PU is shown in FIG. 5. FIG. 5 depicts an ALU based PU 150 having inputs from secondary data 38, K+1 taps 152 from selectable multiplexer 90 (T(0), through T(K)), and N1 PU outputs 154 from the other PUs in the configurable processing array. N1 is the number of PUs in the array. These inputs are supplied to a N1*(K+1)*1:2 multiplexer 156. The multiplexer 156 outputs data to the inputs of the ALU 158 which can be programmed (along with the multiplexer 156) via the program input 160 to carry out the desired operation. PU 150 is an example of PU 104, with the data formatting circuitry having a multiplexer 156.

The configurable logic array may incorporate a plurality of either or both of types of PU along with other logic and or analog circuit functions that can be configured by program control. Several commercially available processors incorporate similar configurable PU elements in a processing array that can be configured under program control. The variable delay line and the configurable processor array can be programmed using any suitable programmable processor. Those skilled in the art will also appreciate upon consideration of this teaching that the program steps and associated data used to implement such programming can use any suitable computer readable storage medium such as for example disc storage, Read Only Memory (ROM) devices, Random Access Memory (RAM) devices, semiconductor storage elements, optical storage elements, magnetic storage elements, magneto-optical storage elements, flash memory, core memory and/or other equivalent storage technologies.

By use of the present architecture, numerous complex processing operations can be carried out by software configuration or reconfiguration of the variable length delay line 10, tuning circuit 28 and configurable processing array 32. By way of example, clock generation functions, CDMA correlation, waveform generation, and other operations can be carried out in the same circuit. Moreover, compound complex system functions can be implemented by reconfiguration of the configurable circuits periodically (e.g., every clock or symbol cycle) to enable reuse of the same circuitry to perform multiple functions, thereby conserving circuitry and power. Several illustrative examples of circuit configurations follow.

With reference to FIG. 6, a 4× frequency multiplier where N=8 is depicted using the configurable circuitry just described. In this embodiment, a clock signal from clock 52 at frequency F_{IN} is routed to the input of the variable delay line 10 at delay element 12. The delay line is locked so that tap T(0) and tap T(8) are locked to one wavelength of the reference clock 52. The configurable processing array 32 is configured to receive tap outputs T(1) through T(4), which are active in this circuit configuration. Taps T(5) through T(N) can be turned off. Taps T(1) and T(2) are received by an exclusive OR (XOR) gate 56 and taps T(3) and T(4) are received by an XOR 60. The outputs of XORs 56 and 60 are provided to a third XOR gate 64 which produces an output 42 that is four times the input F_{IN}. The XOR functions can be realized using PUs or programmable logic gates configured to carry out an XOR function.

Tuning of the delay line 10 in this example is accomplished by use of a delay lock loop. A phase detector 68 compares a phase difference between any two selected output taps with one another. In this case, the outputs T(0) and T(8) are inputs into the phase detector. In this example, the delay elements which do not connect to the configurable processing array remain active for purposes of permitting the delay locked loop to lock and continue to maintain the proper TUNE signal 26 to the delay line 10. The output of the phase detector 68 drives a charge pump 72 in accordance with the difference in phase between the two inputs of the phase detector 68. A capacitor 76 stores the charge from the charge pump to produce the TUNE signal 26 voltage that adjusts the delay line 10's delay.

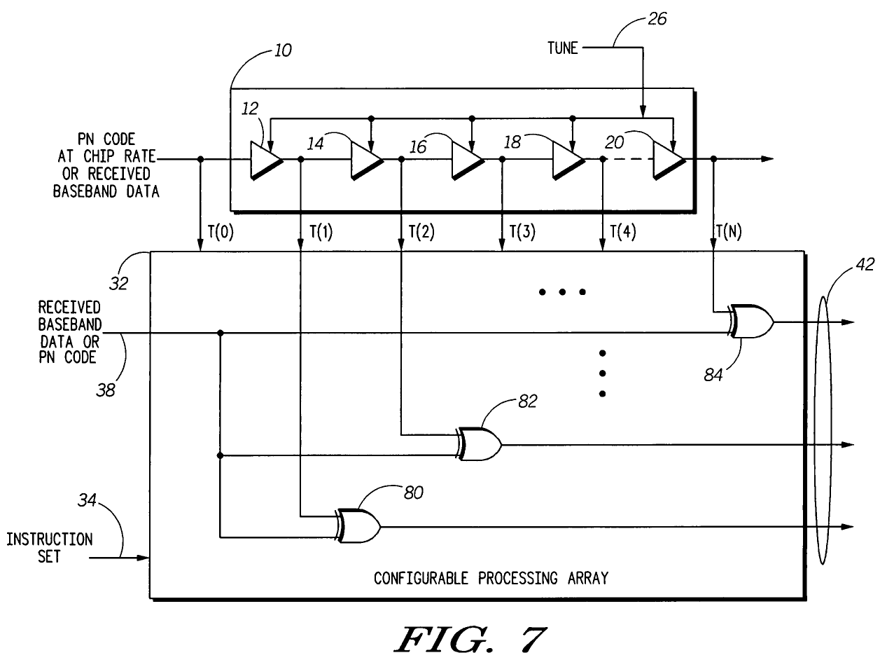

The same circuit can be configured or reconfigured under software control to implement many other circuits. FIG. 7 depicts an exemplary CDMA correlator circuit configuration. In this configuration, the input of the variable delay line is driven by a PN code (Pseudorandom Noise code) at the code's chip rate. The delay line is tuned by the tune signal 26 so that the delay of one buffer (12,14,16,18, 20) is one-half or a fraction the chip rate. Input 38 of the configurable processing array 32 is provided with received baseband data. In this case each of the N output taps is used in the processing. The received baseband data are combined with the output at each delay tap T(1) through T(N) using XOR gates 80, 82 through 84 to produce N correlated outputs 42. Again, the XOR functions can be realized using PUs or programmable logic gates configured to carry out an XOR function. The correlated outputs 42 are the received baseband data demodulated with delayed versions of the PN code at a fraction of the chip rate. The correlated outputs 42 are then accumulated over a symbol. Equivalently, the received baseband data can be inputted into the delay line and the secondary input 38 is the PN code at the chip rate. This produces equivalent correlated outputs 42 that are delayed versions of the received baseband data demodulated with the PN code.

While certain specific embodiments have been described, it is evident that many alternatives, modifications, permutations and variations will become apparent to those of ordinary skill in the art in light of the foregoing description. Accordingly, it is intended that the present invention embrace all such alternatives, modifications and variations as fall within the scope of the appended claims.

1. A configurable circuit, comprising:
a variable length delay line, the delay line having an input and having N delay elements to provide a plurality of N delayed outputs;
the variable length delay line having a number of active delay elements determined by a program command; and
a configurable processing array receiving the delayed outputs from the active delay elements and secondary processing data, the configurable processing array comprising an array of configurable circuit elements.

2. The configurable circuit according to claim 1, further comprising a control processor that configures the number of active delay elements of the variable length delay line and configures the array of configurable circuit elements.

3. The configurable circuit according to claim 1, wherein the delay of the N delay elements is controlled by the control processor.

4. The configurable circuit according to claim 1, wherein the delay of the N delay elements is controlled by an output of a delay locked loop.

5. The configurable circuit according to claim 1, wherein each of the N delay elements comprises a pair of series connected inverters.

6. The configurable circuit according to claim 1, wherein the configurable processing array further comprises an input and an output that can be configured under program control.

7. The configurable circuit according to claim 1, wherein the configurable processing array further comprises a plurality of outputs that can be configured under program control.

8. The configurable circuit according to claim 1, wherein the configurable circuits comprise a plurality of configurable processing units (PUs).

9. The configurable circuit according to claim 1, wherein the configurable circuits comprise a programmable logic device.

10. The configurable circuit according to claim 1, further comprising a programmable multiplexer, responsive to the program control command to selectively enable a selected group of delay elements while disabling remaining delay elements.

11. A configurable circuit, comprising:
a variable length delay line, the delay line having an input and having N delay elements to provide a plurality of N delayed outputs;
the N delay elements each comprising a pair of series connected inverters;
the variable length delay line having a number of active delay elements determined by a program command;
a configurable processing array receiving the delayed outputs from the active delay elements and secondary processing data, the configurable processing array comprising an array of configurable circuit elements;
a control processor that configures the number of active delay elements of the variable length delay line and configures the array of configurable circuit elements; and
a delay locked loop controlling the delay of the N delay elements.

12. The configurable circuit according to claim 11, wherein the configurable processing array further comprises an input and an output that can be configured under program control.

13. The configurable circuit according to claim 11, wherein the configurable processing array further comprises a plurality of outputs that can be configured under program control.

14. The configurable circuit according to claim 11, wherein the configurable circuits comprise a plurality of configurable processing units (PUs).

15. The configurable circuit according to claim 11, wherein the configurable circuits comprise a programmable logic device.

16. The configurable circuit according to claim 11, further comprising a programmable multiplexer, responsive to the program control command to selectively enable a selected group of delay elements while disabling remaining delay elements.

17. A method of performing a circuit function, comprising:
applying an input to a variable length delay line, the delay line having an input and having N delay elements to provide a plurality of N delayed outputs, the variable length delay line having a number of active delay elements determined by a program command; and
applying the delayed outputs of the active delay elements to a configurable processing array receiving the delayed outputs from the active delay elements and secondary processing data, the configurable processing array comprising an array of configurable circuit elements that have been configured under program control to carry out a circuit function.

18. The method according to claim 17, further comprising programming the variable length delay line and the configurable processing array using a control processor that configures the number of active delay elements of the variable length delay line and configures the circuit function of the array of configurable circuit elements.

19. The method according to claim 17, further comprising controlling the delay of the N delay elements to achieve a selected overall delay.

20. The method according to claim 17, wherein the configurable processing array further comprises an input and an output that are configured under program control.

21. The method according to claim 17, wherein the configurable circuits comprise at least one of a plurality of configurable processing units (PUs) and a programmable logic device.

22. A variable delay line, comprising:
a plurality of N delay elements with each delay having an input and an output, the N delay elements being coupled together in series output to input to form a delay line;
a programming input that receives a program control command; and
a programmable multiplexer, responsive to the program control command to selectively enable a selected group of delay elements while disabling remaining delay elements.

23. The variable delay line according to claim 22, further comprising a delay control input, and wherein the delay of the N delay elements is controlled by a signal applied to the delay control input.

24. The variable delay line according to claim 23, wherein the delay of the N delay elements is controlled by an output from one of a control processor and a delay locked loop.

25. The variable delay line according to claim 22, wherein each of the N delay elements comprises a pair of series connected inverters.

26. A variable delay line, comprising:
a plurality of N delay elements with each delay having an input and an output, the N delay elements being coupled together in series output to input to form a delay line;
a programming input that receives a program control command;
a programmable multiplexer, responsive to the program control command to selectively enable a selected group of delay elements while disabling remaining delay elements; and
a delay control input, wherein the delay of the N delay elements is controlled by a signal applied to the delay control input.

27. The variable delay line according to claim 26, wherein the delay of the N delay elements is controlled by an output from one of a control processor and a delay locked loop.

28. The variable delay line according to claim 26, wherein each of the N delay elements comprises a pair of series connected inverters.
